(19) United States
(12) Patent Application Publication
(10) Pub. No.: US 2025/0142843 A1
(43) Pub. Date: May 1, 2025

(54) INTEGRATED DEEP TRENCH CAPACITOR HAVING HIGH CAPACITANCE DENSITY AND VOLTAGE LINEARITY

(71) Applicant: Texas Instruments Incorporated, Dallas, TX (US)

(72) Inventors: Poornika Gayathri Fernandes, Murphy, TX (US); Jack Qian, Plano, TX (US)

(21) Appl. No.: 18/498,811

(22) Filed: Oct. 31, 2023

(51) Int. Cl. H01L 29/94; H01L 27/07; H01L 29/66

(52) U.S. Cl. CPC H10D 1/665; H10D 1/047; H10D 84/811

(57) ABSTRACT

An integrated circuit including an integrated trench capacitor in a substrate. The trench capacitor includes a plurality of deep trenches extending into the substrate, the trenches filled with a conductive trench-fill material. A first subset of the trenches located in an N-type well and a second subset of the trenches located in a P-type well. A first capacitor terminal connects the conductive trench-fill material in the first subset of trenches and the conductive trench-fill material in the second subset of trenches. A second capacitor terminal connects the N-type well and the P-type well.

### FIELD

This disclosure relates to the field of microelectronic devices. More particularly, but not exclusively, this disclosure relates to integrated capacitors in microelectronic devices.

### BACKGROUND

Integrated capacitors are used in some microelectronic devices. Such capacitors, including deep trench capacitors, have a capacitance vs. Voltage (C-V) characteristic that typically is nonlinear to some extent. Such nonlinearity may be undesirable in some applications.

### SUMMARY

The present disclosure introduces an integrated circuit including an integrated deep trench capacitor, hereinafter referred to as a “trench capacitor”, in a substrate. The trench capacitor includes a plurality of deep trenches extending into the substrate, the trenches filled with a conductive trench-fill material. A first subset of the trenches are located in an N-type well and a second subset of the trenches are located in a P-type well. A first capacitor terminal connects the conductive trench-fill material in the first subset of trenches and the conductive trench-fill material in the second subset of trenches. A second capacitor terminal connects the N-type well and the P-type well. Trench capacitors consistent with the disclosure may provide improved linearity of capacitance vs. Voltage as compared to baseline trench capacitors.

### BRIEF DESCRIPTION OF THE VIEWS OF THE DRAWINGS

FIG. 1A through FIG. 1J are cross sections of an example microelectronic device with a trench capacitor, depicted in successive stages of an example method of formation.

FIG. 2 discloses a top-down view of the layout of a microelectronic device containing trench capacitor.

FIG. 3 shows a capacitance vs. Voltage (C-V) characteristic of a device consistent with described examples.

FIG. 4 shows an integrated circuit (IC) that includes the trench capacitor.

### DETAILED DESCRIPTION

The present disclosure is described with reference to the attached figures. The figures are not drawn to scale and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

In addition, although some of the examples illustrated herein are shown in two dimensional views with various regions having depth and width, it should be clearly understood that these regions are illustrations of only a portion of a device that is actually a three-dimensional structure. Accordingly, these regions will have three dimensions, including length, width, and depth, when fabricated on an actual device. Moreover, while the present disclosure is illustrated by examples directed to active devices, it is not intended that these illustrations be a limitation on the scope or applicability of the disclosure. It is not intended that the active devices of various described examples be limited to the physical structures illustrated. These structures are included to demonstrate the utility and application of various implementations.

A microelectronic device is formed in and on a substrate having a semiconductor material. The microelectronic device includes a trench capacitor in the substrate. The trench capacitor consists of a first deep trench and a second deep trench. The first deep trench and the second deep trench are lined with a dielectric material. The first deep trench is in a first conductivity type region, the first conductive type region forming the capacitor first bottom plate, the capacitor first bottom plate being conductively connected to a first capacitor terminal. The second deep trench is in a second conductivity type region which forms the capacitor second bottom plate, the capacitor second bottom plate being conductively connected to a second capacitor terminal. In various examples, and as described below, the first conductivity type is p-type and the second conductivity type is n-type, while in other examples the conductivity types are reversed such that the first conductivity type is n-type and the second conductivity type is p-type. A conductive capacitor fill material in the first trench and in the second trench forms the top plate of the capacitor. The top plate of the capacitor is electrically connected to a second capacitor terminal. The first capacitor terminal and third capacitor terminal may be in electrical contact with each other, or the first capacitor terminal and the third capacitor terminal may be electrically isolated from each other. It is advantageous to for the first trench and the second trench to have bottom plates of opposite conductivity as the opposite conductivity may give improved capacitor linearity to an applied voltage.

The microelectronic device has a field oxide layer on the semiconductor material, extending between the deep trenches. The field oxide layer also covers a portion of the trench-fill material in each of the deep trenches, with a trench contact opening over the trench-fill material in each deep trench. The trench-fill material extends through each trench contact opening. A metal silicide layer is located on the trench-fill material in each trench contact opening. A silicide blocking layer is located over the field oxide layer, overlapping the capacitor dielectric layer. The silicide blocking layer is free of the metal silicide layer. The trench capacitor is free of the metal silicide layer between the deep trenches.

It is noted that terms such as top, over, above, under, and below may be used in this disclosure. These terms should not be construed as limiting the position or orientation of a structure or element, but should be used to provide spatial relationship between structures or elements.

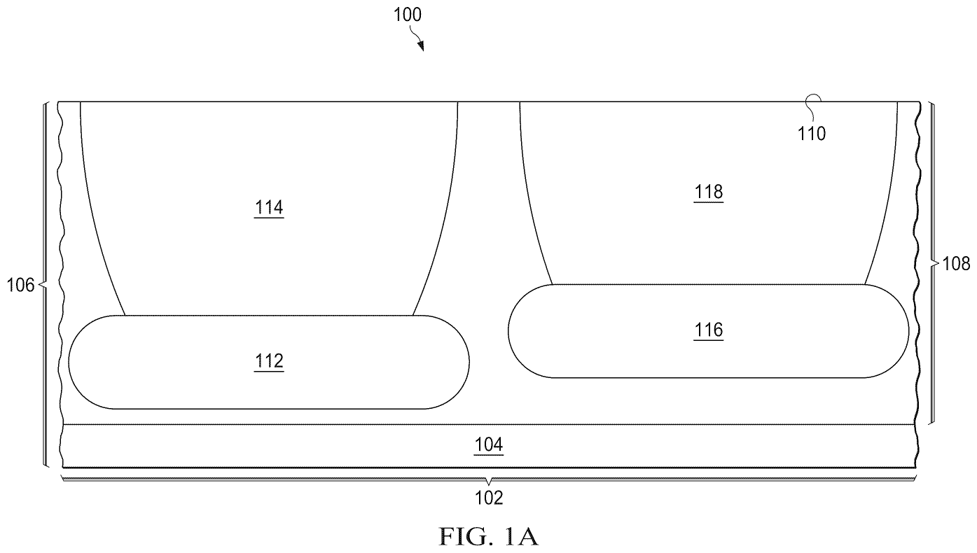

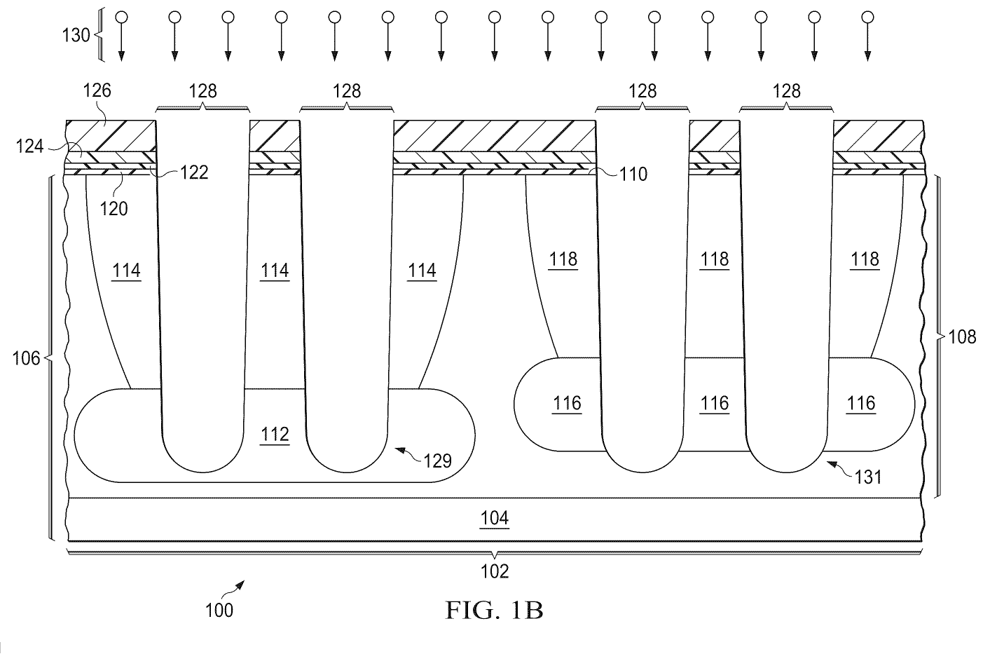

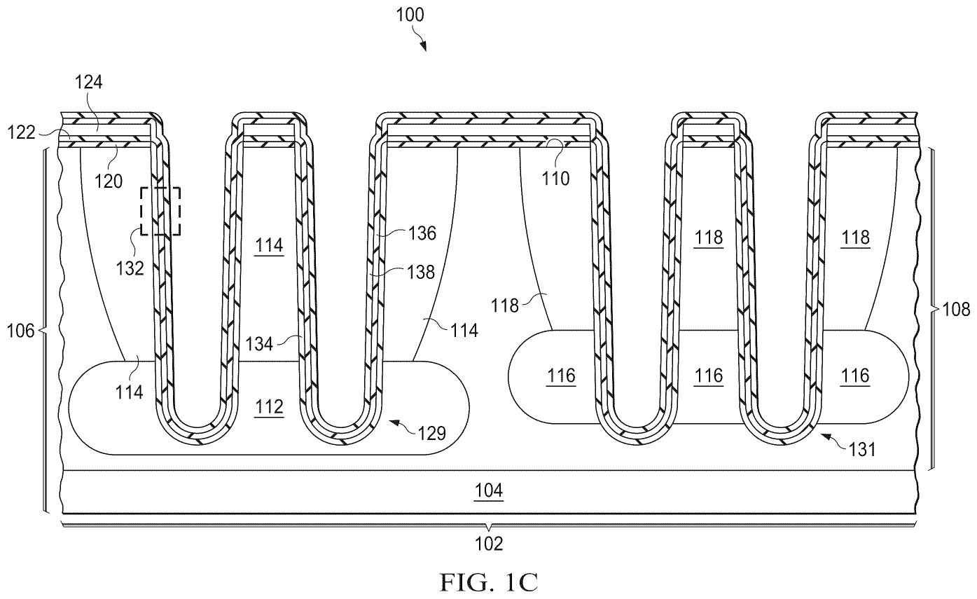

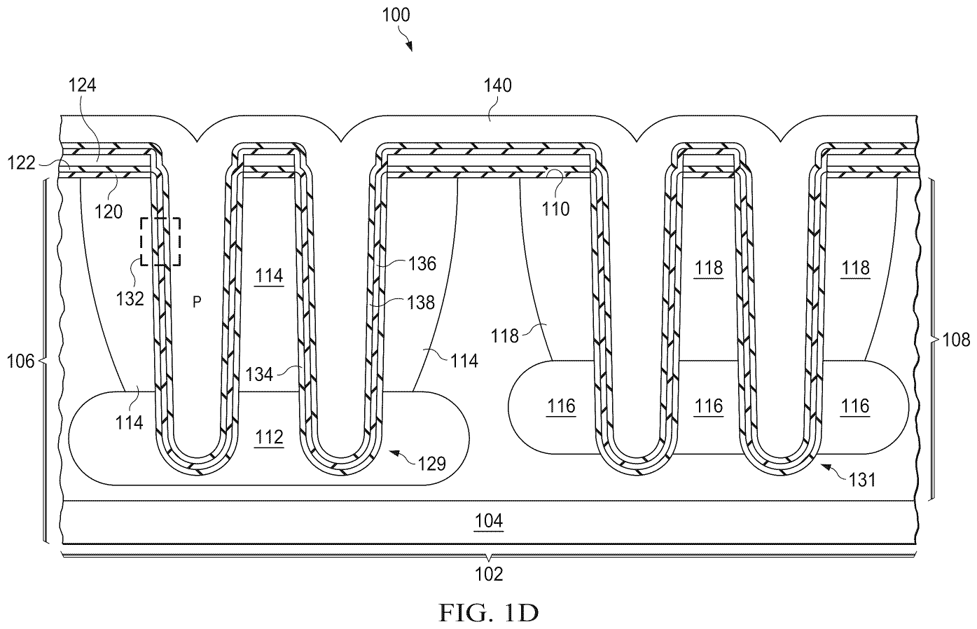

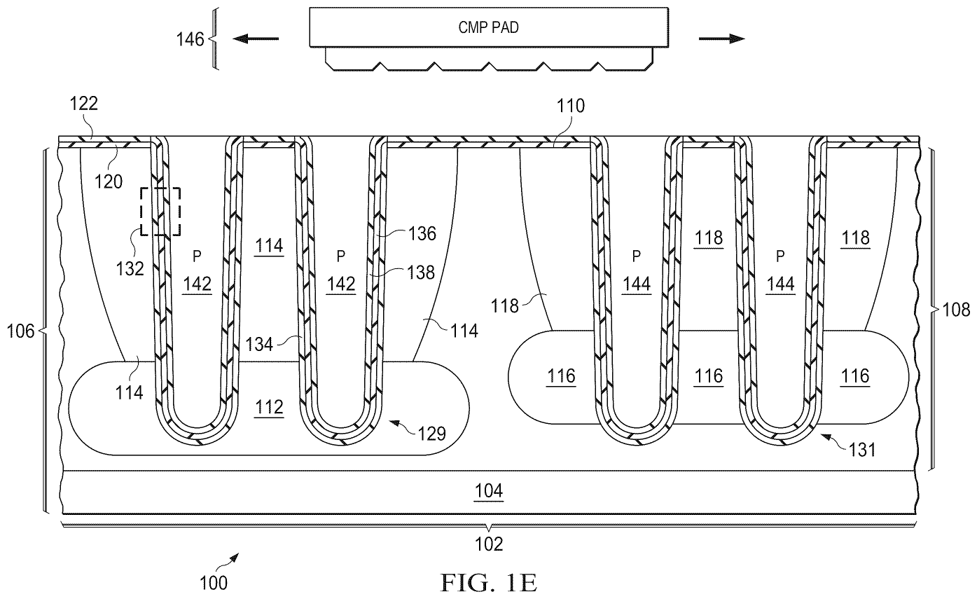

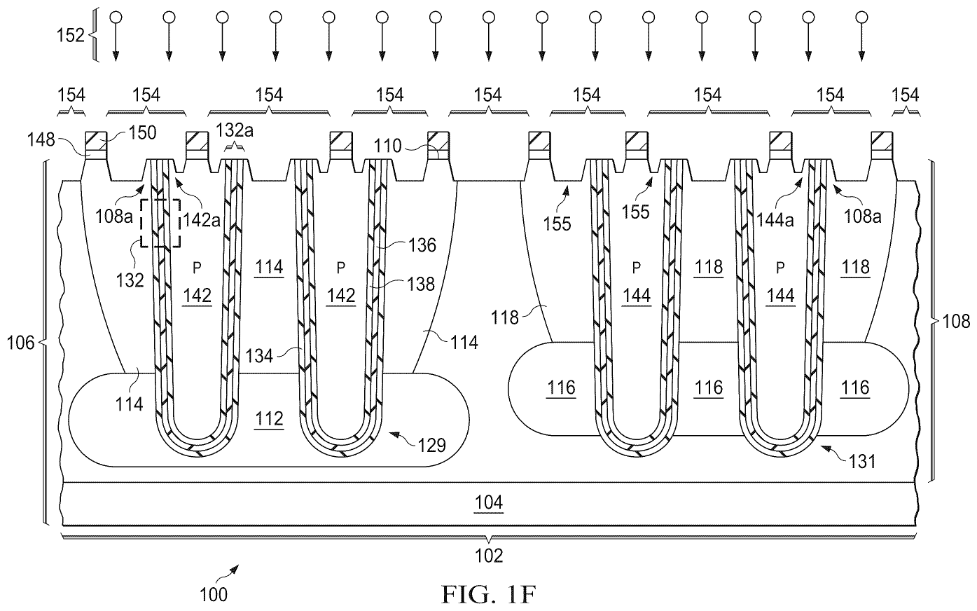

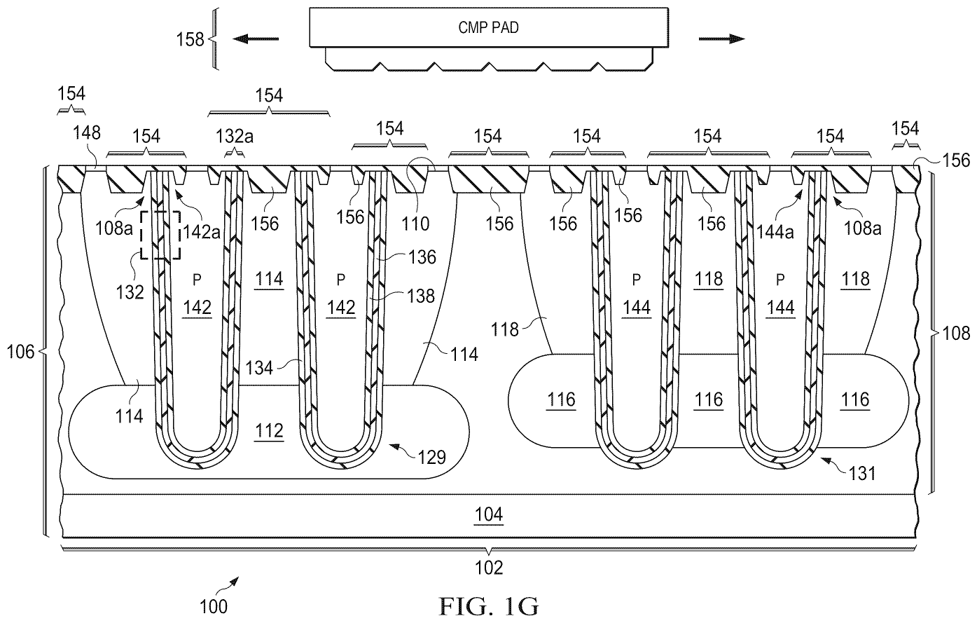

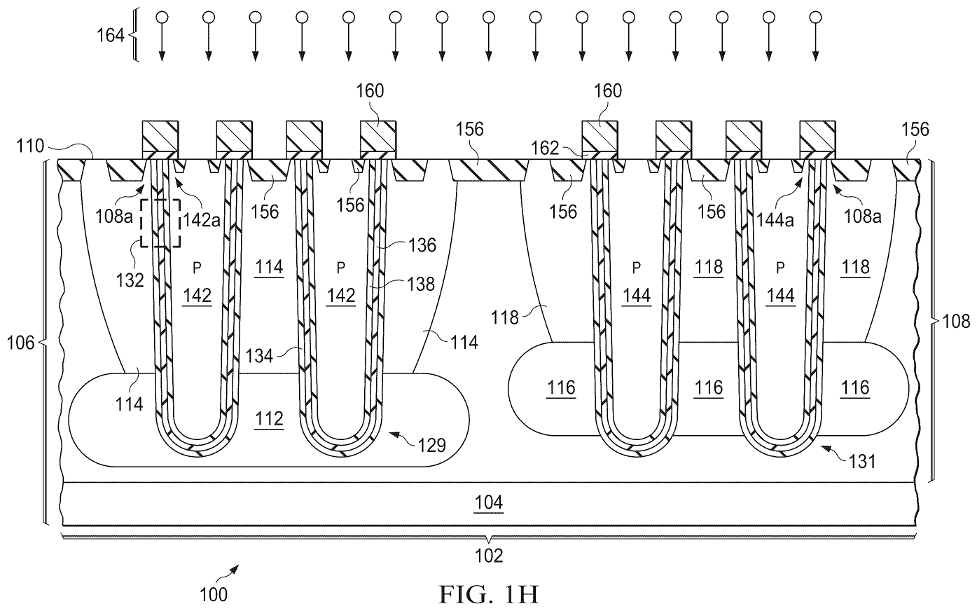

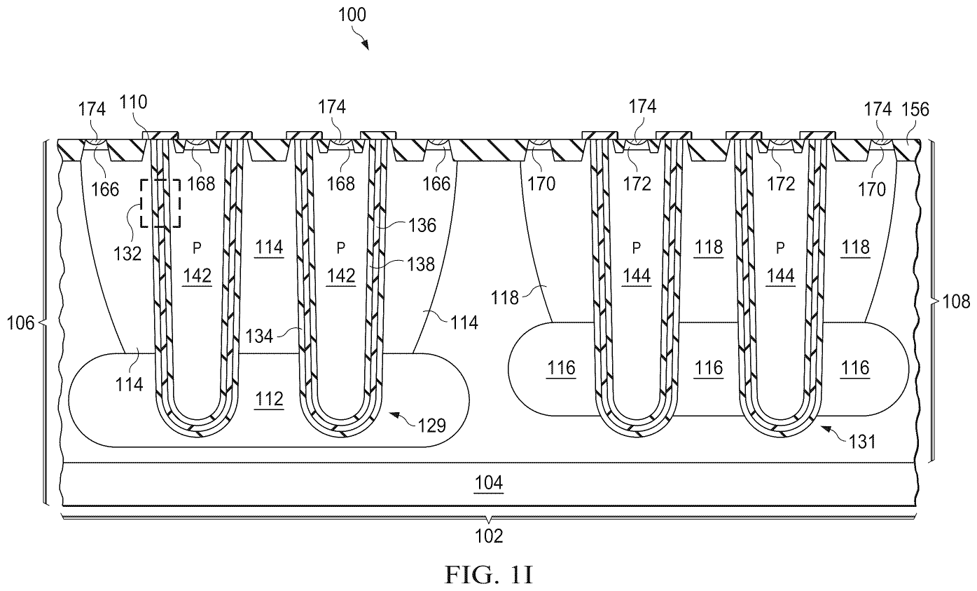

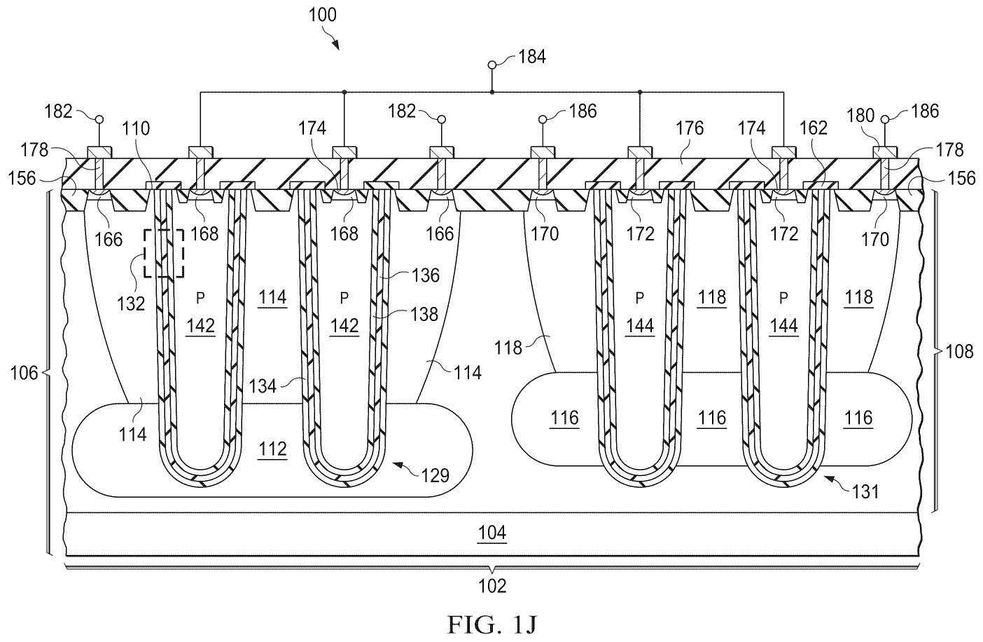

FIG. 1A through FIG. 1J are cross sections of an example microelectronic device 100 with a trench capacitor 102, depicted in successive stages of an example method of formation. Referring to FIG. 1A, the microelectronic device 100 is formed in and on a substrate 106. In this example, the substrate 106 may include a base wafer 104, such as a silicon wafer. The base wafer 104 may have a first conductivity type, which is p-type in this example, as indicated in FIG. 1A. In an alternate version of this example, the base wafer 104 may include a dielectric material, such as silicon dioxide or sapphire, to provide a silicon-on-insulator substrate. The substrate 106 of this example also includes a semiconductor material 108 formed on the base wafer 104. The semiconductor material 108 includes primarily silicon, and may consist essentially of silicon and dopants, such as boron. The semiconductor material 108 may be an epitaxial layer, and may be lightly doped, e.g. 10¹⁵-10¹⁶ cm⁻³. The semiconductor material 108 extends to a top surface 110 of the substrate 106, located on an opposite surface of the semiconductor material 108 from a boundary between the semiconductor material 108 and the base wafer 104. In this example, the semiconductor material 108 may be doped with boron to have the first conductivity type, e.g. P-type, as indicated in FIG. 1A. The semiconductor material 108 may be 5 μm to 15 μm thick, by way of example.

A first buried layer 112 may be formed in the substrate 106. In the example microelectronic device 100, the first buried layer 112 has the second conductivity type, e.g. N-type. A second buried layer 116 may be formed in the substrate 106. The second buried layer has the first conductivity type, e.g. P-type. The first buried layer 112 may be formed by implanting dopants of the second conductivity type, such as phosphorus, arsenic, or antimony, into the substrate 106. The second buried layer 116 may be formed by implanting dopants of the first conductivity type, such as boron or indium into the substrate 106.

A first deep well 114 may be formed in the semiconductor material 108, extending from the top surface 110 of the substrate 106 and contacting the first buried layer 112. The first deep well 114 has the second conductivity type. The first deep well 114 may be formed by implanting dopants of the second conductivity type, such as phosphorus, into the semiconductor material 108, followed by a thermal drive to diffuse the implanted dopants to the first buried layer 112 and activate the implanted dopants. The first deep well 114 may have an average concentration of the dopants of the second conductivity type that greater than twice an average concentration of dopants in the semiconductor material 108 outside of the first deep well 114.

A second deep well 118 may be formed in the semiconductor material 108, extending from the top surface 110 of the substrate 106 and contacting the second buried layer 116. The second deep well 118 may have the first conductivity type. The second deep well 118 may be formed by implanting dopants of the first conductivity type, such as boron or indium into the semiconductor material 108, followed by a thermal drive to diffuse the implanted dopants to the second buried layer 116 and activate the implanted dopants. The second deep well 118 may have an average concentration of the dopants of the first conductivity type that greater than twice an average concentration of dopants in the semiconductor material 108 outside of the second deep well 118.

Referring to FIG. 1B, a pad oxide layer 120 may be formed on the top surface 110 of the substrate 106. The pad oxide layer 120 may include primarily silicon dioxide, may be formed by a thermal oxidation process or a thermal chemical vapor deposition (CVD) process, and may have a thickness of 50 nm to 200 nm, by way of example. A nitride cap layer 122 may be formed on the pad oxide layer 120. The nitride cap layer 122 may include primarily silicon nitride, may be formed by a low-pressure chemical vapor deposition (LPCVD) furnace process, and may have a thickness of 100 nm to 500 nm. A hard mask layer 124 may be formed on the nitride cap layer 122. The hard mask layer 124 may include primarily silicon dioxide, may be formed by a plasma enhanced chemical vapor deposition (PECVD) process, and may have a thickness of 1 μm to 3 μm. The pad oxide layer 120 may provide stress relief between the semiconductor material 108 and a combination of the nitride cap layer 122 and the hard mask layer 124. The nitride cap layer 122 may provide a stop layer for subsequent etch and planarization processes. The hard mask layer 124 may provide a hard mask during a subsequent deep trench etch process 130 to form first deep trenches 129 and second deep trenches 131.

A resist layer 126 with deep trench openings 128 may be formed on the hard mask layer 124. The resist layer 126 may include photoresist, and may optionally include anti-reflection material such as a bottom anti-reflection coat (BARC). The resist layer 126 may be formed by a photolithographic process.

A deep trench etch process 130 is performed to form a plurality of trenches, the first deep trenches 129 being a subset of the plurality of trenches located in the first deep well 114, and the second deep trenches 131 being a subset of the plurality of trenches located in the second deep well 118. The deep trench etch process 130 may include multiple steps. The first deep trenches 129 extend from the top surface 110 into the first deep well 114 and first buried layer 112 and are surrounded by doping of the first conductivity type. The second deep trenches 131 extend from the top surface 110 into the second deep well 118, into the second buried layer 116 and may be in the substrate 106 under the second buried layer 116. The second deep trenches 131 are surrounded by doping of the second conductivity. While the example microelectronic device 100 describes an example method to achieve first deep trenches 129 surrounded by doping of the second conductivity type and second deep trenches 131 surrounded by doping of the first conductivity type, other methods of achieving equivalent doping of the semiconductor material 108 contacting the first deep trenches 129 and the second deep trenches 131 are within the scope of the disclosure.

Referring to FIG. 1C, a capacitor dielectric layer 132 is formed in the first deep trenches 129 and the second deep trenches 131, contacting the semiconductor material 108 of the substrate 106. The capacitor dielectric layer 132 may extend over the hard mask layer 124, the nitride cap layer 122, and the pad oxide layer 120. The capacitor dielectric layer 132 includes a silicon-nitrogen compound, and may include silicon dioxide or other dielectric material. In this example, the capacitor dielectric layer 132 may include an outer layer 134 contacting the semiconductor material 108 of the substrate 106, a center layer 136 on the outer layer 134, and an inner layer 138 on the center layer 136.

The outer layer 134 may include silicon dioxide, and may be formed by a thermal oxidation process which oxidizes silicon in the substrate 106 at the surface of the first deep trenches 129 and the second deep trenches 131. The outer layer 134 may be at least 3 nm thick, to provide low leakage current in the trench capacitor 102 during operation of the microelectronic device 100, and may be 6 nm to 10 nm thick, depending on an operating potential of the trench capacitor 102.

The center layer 136 includes the silicon-nitrogen compound, which may be implemented as silicon nitride or silicon oxynitride. The center layer 136 may be formed by a CVD process or an LPCVD process using a silicon-containing reagent gas and a nitrogen-containing reagent gas, not specifically shown. The silicon-containing reagent gas may be implemented as silane or dichlorosilane. The nitrogen-containing reagent gas may be implemented as ammonia or hydrazine. Alternatively, the silicon-containing reagent gas and the nitrogen-containing reagent gas may be implemented as bis(tertiary-butyl-amino) silane (BTBAS). A thickness of the center layer 136 may be selected to provide a desired capacitance density and breakdown potential for the trench capacitor 102. By way of example, the center layer 136 may be 12 nm thick to provide a breakdown potential greater than 12 volts. In another version of this example, the center layer 136 may be 8 nm to 40 nm thick. Having the silicon-nitrogen compound in the capacitor dielectric layer 132 may advantageously provide more reliability and higher operating potential compared to a dielectric layer without the silicon-nitrogen compound.

The inner layer 138 may include primarily silicon dioxide or silicon oxynitride, to reduce charge trapping in the capacitor dielectric layer 132 and to provide a suitable interface to a subsequently formed trench-fill material 140, shown in FIG. 1D. The inner layer 138 may be formed by a CVD process or an LPCVD process using the silicon-containing reagent gas and an oxygen-containing reagent gas and optionally using the nitrogen-containing reagent gas, if nitrogen is needed to form the inner layer 138. The oxygen-containing reagent gas may be implemented as oxygen or nitrous oxide. Alternatively, the silicon-containing reagent gas and the oxygen-containing reagent gas may be implemented as tetraethoxysilane (TEOS), also referred to as tetraethyl orthosilicate. The inner layer 138 may have a thickness of 40 nm to 60 nm immediately after being formed. A trench dielectric etch process (not specifically shown) may be performed after the inner layer 138 is formed to improve thickness uniformity of the inner layer 138 along sidewalls of the first deep trenches 129 and the second deep trenches 131.

Referring to FIG. 1D, the trench-fill material 140 is formed in the first deep trenches 129 and the second deep trenches 131 on the capacitor dielectric layer 132. The trench-fill material 140 is electrically conductive. The trench-fill material 140 includes primarily silicon, and may be implemented as polycrystalline silicon, commonly referred to as polysilicon. Alternatively, the trench-fill material 140 may be implemented as amorphous silicon, or semi-amorphous silicon. The trench-fill material 140 may have the first conductivity type, p-type in this example, as indicated in FIG. 1D. For example, the trench-fill material 140 may have an average concentration of dopants of 5×10¹⁸ cm⁻³ and 1×10²⁰ cm⁻³, to provide a low equivalent series resistance for the trench capacitor 102.

The trench-fill material 140 may be formed by thermal decomposition of a silicon-containing reagent gas that includes dopants. The trench-fill material 140 fills the first deep trenches 129 and the second deep trenches 131, and may extend over the substrate 106 outside of the first deep trenches 129 and the second deep trenches 131, as depicted in FIG. 1D.

Referring to FIG. 1E, the trench-fill material 140 and the capacitor dielectric layer 132 are removed from outside of the first deep trenches 129 and the second deep trenches 131. The trench-fill material 140 and the capacitor dielectric layer 132 may be removed by a planarization process, such as a chemical mechanical polish (CMP) process 146, as indicated in FIG. 1E. Alternatively, the trench-fill material 140 and the capacitor dielectric layer 132 may be removed by an etchback process. The process of removing the trench-fill material 140 and the capacitor dielectric layer 132 leaves the trench-fill material 140 on the capacitor dielectric layer 132 in the first deep trenches 129 and the second deep trenches 131. The process of removing the trench-fill material 140 and the capacitor dielectric layer 132 may leave the nitride cap layer 122 and the pad oxide layer 120 on the top surface 110 of the substrate 106. The nitride cap layer 122 may provide a stop layer for the CMP process 158. The nitride cap layer 122 and the pad oxide layer 120 may be removed in a separate process, after removing the trench-fill material 140 and the capacitor dielectric layer 132 from outside of the first deep trenches 129 and the second deep trenches 131. The trench-fill material 140 remaining in the first deep trenches 129 and the second deep trenches 131 after the CMP process 158 is subsequently referred to as the first trench-fill material 142 and the second trench-fill material 144. While the first trench-fill material 142 and the second trench-fill material 144 of the example device are formed from a common trench-fill material 140, it is within the scope of the disclosure cases where the first trench-fill material 142 and the second trench-fill material 144 are of differing doping concentrations and conductivities.

Referring to FIG. 1F, a CMP stop layer 148 is formed over the top surface 110 of the substrate 106, the capacitor dielectric layer 132, and the trench-fill material 140. The CMP stop layer 148 may include a silicon dioxide layer (not specifically shown) on the substrate 106, the capacitor dielectric layer 132, and the trench-fill material 140, and a silicon nitride layer (not specifically shown) on the silicon dioxide layer. The silicon dioxide layer may be 5 nm to 20 nm thick, and may be formed by a thermal oxidation process. The silicon nitride layer may be 100 nm to 200 nm thick, and may be formed by an LPCVD process. Layers of other materials having a high CMP selectivity to silicon dioxide may be substituted for the silicon nitride layer.

A field oxide mask 150 with field oxide mask openings 154 is formed over the CMP stop layer 148, exposing the CMP stop layer 148 in areas for a field oxide trench, commonly referred to as a shallow trench or a shallow trench isolation (STI) trench. The field oxide mask 150 may include photoresist and may be formed by a photolithographic process. The CMP stop layer 148 is removed where exposed by the field oxide mask 150. The trench etch process 152 removes semiconductor material 108 and material from the top of the first trench-fill material 142 and the second trench-fill material 144 in areas exposed by the field oxide match to form a shallow trench 155 in the substrate 106, the first trench-fill material 142 and the second trench-fill material 144. The shallow trench 155 may extend to a depth of 250 nm to 1 μm in the semiconductor material 108, and to a depth of 200 nm to 800 nm in the first trench-fill material 142 and the second trench-fill material 144, by way of example.

The trench etch process 152 may be implemented as a two-step process, in which a first etch step removes the CMP stop layer 148, and a second etch step removes the semiconductor material 108 and the trench-fill material 140. The first etch step may be implemented as a reactive ion etch (RIE) process using fluorine and oxygen, for example. The second etch step may be implemented as an RIE process using one or more halogens, for example. The trench etch process 152 removes the capacitor dielectric layer 132 at a lower rate than the semiconductor material 108, and at a lower rate than the trench-fill material 140, so that a portion 132a of the capacitor dielectric layer 132 extends into the shallow trench 155. A portion 108a of the semiconductor material 108 contacting the portion 132a of the capacitor dielectric layer 132 may extend into the shallow trench 155, as a secondary result of the low etch rate of the capacitor dielectric layer 132. A portion 144a of the trench-fill material 140 contacting the portion 132a of the capacitor dielectric layer 132 may extend into the shallow trench 155, as another secondary result of the low etch rate of the capacitor dielectric layer 132. After the shallow trench 155, the field oxide mask 150 may be removed.

Referring to FIG. 1G, a field oxide layer 156 is formed in the shallow trench 155. The field oxide layer 156 may be planarized by a CMP process 158. The field oxide layer 156 may include primarily silicon dioxide, or silicon dioxide-based dielectric material, formed by one or more CVD processes alternated with etchback processes to provide complete filling of the shallow trench 155. After the field oxide layer 156 is planarized, the CMP stop layer 148 is removed. In various examples the field oxide layer 156 is an STI structure.

Referring to FIG. 1H, silicide blocking layer 162 is formed over the top surface 110 of the substrate 106. The silicide blocking layer 162 may include one or more layers of silicon dioxide, silicon nitride, silicon oxynitride, or other dielectric material which is essentially unreactive with metals, such as titanium, cobalt, nickel, or platinum, that are used to form metal silicide. One or more of the portions 132a of the capacitor dielectric layer 132, along with one or more of the portions 108a of the semiconductor material 108, or one or more of the portions 142a of the first trench-fill material 142, or both, may contact the silicide blocking layer 162, or may be separated from the silicide blocking layer 162 by less than 10 nm of silicon dioxide.

A silicide blocking mask 160 is formed over the silicide blocking layer 162 that covers the silicide blocking layer 162 over the portions 132a of the capacitor dielectric layer 132, and exposes the silicide blocking layer 162 in areas for the first substrate contact region 166, the second substrate contact region 170, the first trench contact region 168 and the second trench contact region 172. The silicide blocking mask 160 may include photoresist, and may be formed by a photolithographic process.

The silicide blocking layer 162 is removed where exposed by the silicide blocking mask 160, leaving the silicide blocking layer 162 over the portions 132a of the capacitor dielectric layer 132. The silicide blocking layer 162 may be removed by an RIE process 164 using fluorine, and optionally oxygen. After the silicide blocking layer 162 is removed where exposed by the silicide blocking mask 160, the silicide blocking mask 160 is removed.

Referring to FIG. 1I, implants of the second conductivity type with energies and doses similar to source/drain implants form a first substrate contact region 166 in the first deep well 114. For example, the first substrate contact region 166 may N-type and heavily doped (e.g. 10¹⁹ cm⁻³ or greater). Implants with the same conductivity as the first trench-fill material 142 and energies and doses similar to source/drain implants form a first trench contact region 168 in the first trench-fill material 142. For example, the first trench contact region 168 may P-type and heavily doped (e.g. 10¹⁹ cm⁻³ or greater). Similarly implants of the first conductivity type with energies and doses similar to source/drain implants form a second substrate contact region 170 in the second deep well 118. Implants with the same conductivity as the second trench-fill material 144 and energies and doses similar to source/drain implants form a second trench contact region 172 in the second trench-fill material 144.

In some examples, a metal silicide layer 174 may be formed on the first substrate contact region 166, the first trench contact region 168, the second substrate contact region 170 and the second trench contact region 172. The metal silicide layer 174 may provide ohmic electrical connections to the first substrate contact region 166, the first trench contact region 168, the second substrate contact region 170 and the second trench contact region 172. With lower resistances compared to a similar microelectronic device without metal silicide layer 174.

Referring to FIG. 1J, a pre-metal dielectric (PMD) layer 176 is formed over the top surface 110 of the substrate 106. The PMD layer 176 may include one or more dielectric layers, such as silicon nitride, silicon oxynitride, silicon dioxide, or the like. In some examples, the PMD layer 176 includes a PMD liner and a main dielectric sublayer formed on the PMD liner. Subsequently, the PMD layer 176 may be planarized by a CMP process. Contacts 178, e.g. Tungsten plugs, are formed within the PMD layer 174 to provide electric connection to the first substrate contact region 166, the second substrate contact region 170, the first trench contact region 168 and the second trench contact region 172.

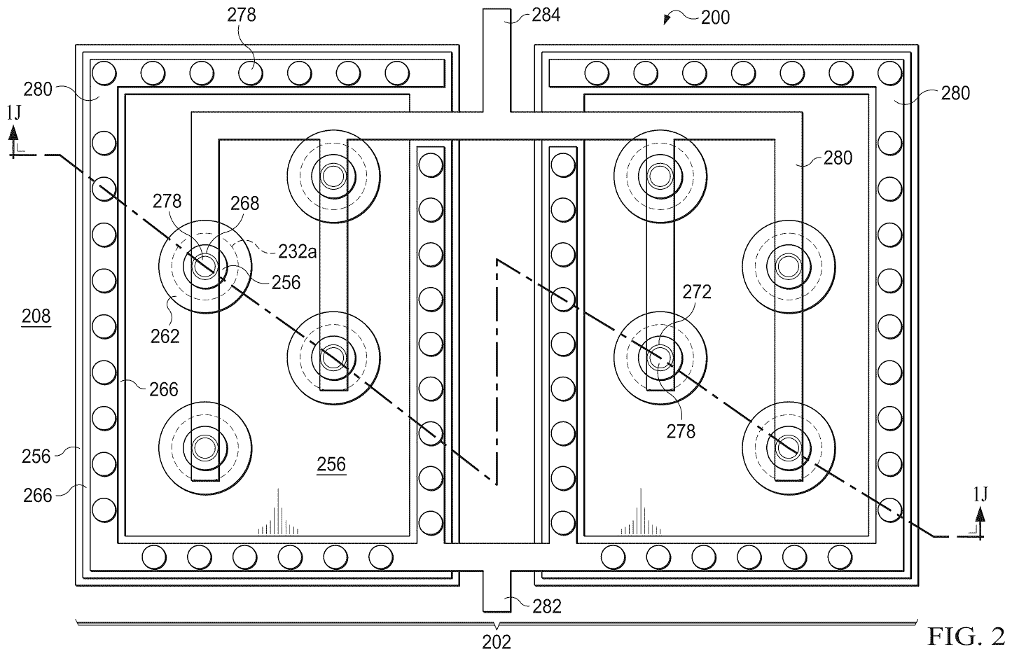

Interconnects 180 electrically connected to the contacts 178 are formed over the PMD layer 176 using any suitable metallization scheme. The first trench contact region 168 and the second trench contact region 172 are connected through contacts 178 and interconnects 180 to an interconnect trace 184 which provides the first terminal of the trench capacitor 102. Interconnect trace 182, which is electrically connected to the first substrate contact region 166, and interconnect trace 186, which is electrically connected to the second substrate contact region 172, provide the second terminal of the trench capacitor 102. The interconnect trace 182 and the interconnect trace 186 may be electrically connected in a manner similar to interconnect trace 282 shown in FIG. 2, or the interconnect trace 182 and the interconnect trace 186 may be may remain separate in use applications in which a three-terminal device is desired. Other components of the microelectronic device 100 may also be connected through the interconnects 180.

FIG. 2 discloses a top-down view of a microelectronic device 200 containing a trench capacitor 202 consistent with the trench capacitor 102. The trench capacitor 202 includes a field oxide layer 256 over the semiconductor material 208. A silicide block region 262 is over a portion of the capacitor dielectric layer 232a, the silicide block region 262 extending into the field oxide layer 256, on both sides of the capacitor dielectric layer 232a. As disclosed in reference to FIG. 1A through FIG. 1J. Contacts 278 and interconnect traces 280 provide an electrical connection between the first trench contact regions 268, the second trench contact regions 272, and a first terminal 284. The field oxide layer 256 includes portions that surround each of the contact regions 268, 272. In other examples, not explicitly shown, the first trench contact regions 268 regions may be connected to a first interconnect trace that may serve as one terminal, and the second trench contact regions 272 may be connected to a second interconnect trace that may serve as another, separate terminal. Additional contacts 278 and interconnect traces 280 provide an electrical connection between a substrate contact region 266 a second terminal 282.

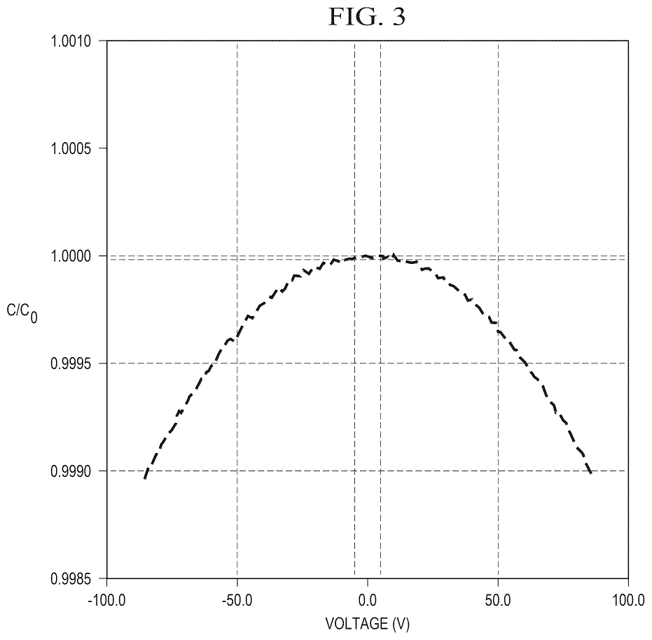

FIG. 3 shows a C-V characteristic of a capacitor constructed according to the principles of the disclosure. The characteristic shows that the capacitance varies by only about 0.1% within a range of about +90 V, less than 500 ppm within a range of about +50 V, and less than 10 ppm within a range of about +5 V. Such an operating characteristic is a significant improvement with respect to baseline trench capacitors, and reduces the need for circuit resources otherwise needed to accommodate greater variability of capacitance with operating voltage.

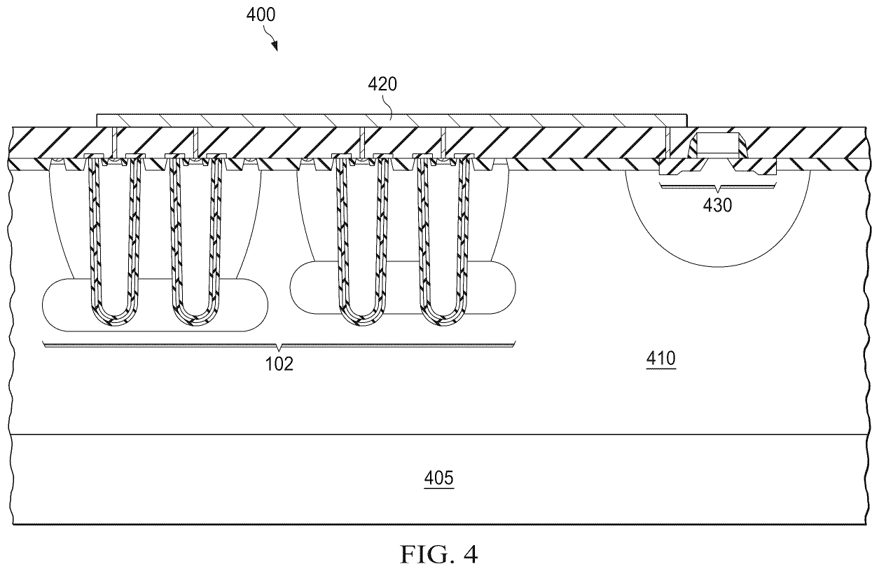

FIG. 4 illustrates an IC 400 that includes the trench capacitor 102. The IC 400 includes a semiconductor substrate 410, such as an epitaxial layer over bulk silicon material 405. The trench capacitor 102 is constructed within the semiconductor substrate 410 as previously described. The IC 400 also includes an electrical component 430, e.g. A transistor that extends into a well region of the semiconductor substrate 410. The component 430 is representative of any number of electrical components located over the semiconductor substrate 410, including transistors, resistors, capacitors and/or inductors. Unreferenced vertical interconnects, or contacts, connect a terminal of the trench capacitor 102 to a metal interconnect trace 420 that in turn connects to a terminal of the component 430. In some other examples the interconnect trace may be implemented in a polysilicon level. The trench capacitor 102 and the component 430 are configured to cooperate to provide an electrical function of the IC 400. The small change of capacitance of the trench capacitor 102 with voltage advantageously provides stable characteristics of the integrated circuit at different operating voltages.

While various examples of the present disclosure have been described above, it should be understood that they have been presented by way of example only and not limitation. Numerous changes to the disclosed examples can be made in accordance with the disclosure herein without departing from the spirit or scope of the disclosure. Thus, the breadth and scope of the present invention should not be limited by any of the above-described examples. Rather, the scope of the disclosure should be defined in accordance with the following claims and their equivalents.

What is claimed is:

1. A integrated circuit, comprising:
a N-type well extending into a semiconductor substrate having a top surface;
a P-type well extending into the semiconductor substrate;
a plurality of trenches extending into the semiconductor substrate, the trenches filled with a conductive trench-fill material, a first subset of the trenches located in the N-type well and a second subset of the trenches located in the P-type well;
a first capacitor terminal that connects to the conductive trench-fill material in the first subset of trenches and the conductive trench-fill material in the second subset of trenches; and
a second capacitor terminal that connects to the N-type well and to the P-type well.

2. The integrated circuit as recited in claim 1, wherein the N-type well connects to an N-type buried layer.

3. The integrated circuit as recited in claim 1, wherein the P-type well connects to a P-type buried layer.

4. The integrated circuit as recited in claim 3, wherein the second subset of trenches extend through the P-type buried layer to a lightly doped epitaxial layer.

5. The integrated circuit as recited in claim 1, wherein the second subset of trenches extends through a P-type buried layer into a lightly doped epitaxial layer.

6. The integrated circuit as recited in claim 1, further comprising a plurality of contacts each connecting to the conductive trench-fill material in a corresponding one of the trenches, and an isolation structure surrounding each of the contacts.

7. The integrated circuit of claim 1, wherein the N-type well and the P-type well both have an average dopant density greater than twice an average dopant concentration of the semiconductor substrate.

8. The integrated circuit of claim 1, wherein the first capacitor terminal or the second capacitor terminal is connected to a transistor terminal.

9. The integrated circuit of claim 1, wherein a capacitance between the first and second capacitor terminals varies by less than 500 ppm with a voltage across the first and second capacitor terminals in a range from −5 V to +5 V.

10. A method of forming an integrated circuit, comprising:
forming an N-type well extending into a semiconductor substrate having a top surface;
forming a P-type well extending into the semiconductor substrate;
forming a plurality of trenches extending into the semiconductor substrate, the trenches, a first subset of the trenches located in the N-type well and a second subset of the trenches located in the P-type well;
filling the trenches with a conductive trench-fill material;
forming a first capacitor terminal that connects to the conductive trench-fill material in the first subset of trenches and to the conductive trench-fill material in the second subset of trenches; and
forming a second capacitor terminal that connects to the N-type well and to the P-type well.

11. The method as recited in claim 10, wherein the N-type well connects to an N-type buried layer.

12. The method as recited in claim 10, wherein the P-type well connects to a P-type buried layer.

13. The method as recited in claim 12, wherein the second subset of trenches extends through a P-type buried layer into a lightly doped epitaxial layer.

14. The method as recited in claim 10, wherein the second subset of trenches extends through a P-type buried layer into a lightly doped epitaxial layer.

15. The method as recited in claim 10, further comprising forming a plurality of contacts each connecting to the conductive trench-fill material in a corresponding one of the trenches, and forming an isolation structure surrounding each of the contacts.

16. The method as recited in claim 10, wherein the N-type well and the P-type well both have an average dopant density greater than twice an average dopant concentration of the semiconductor substrate.

17. The method as recited in claim 10, further comprising connecting the first capacitor terminal or the second capacitor terminal to a transistor terminal.

18. The method of claim 10, wherein a capacitance between the first and second capacitor terminals varies by less than 500 ppm with a voltage across the first and second capacitor terminals in a range from −5 V to +5 V.
